(19) United States
(12) Patent Application Publication
(10) Pub. No.: US 2012/0119269 A1
(43) Pub. Date: May 17, 2012

(54) METHOD FOR PRODUCING ELECTRONIC DEVICE, ELECTRONIC DEVICE, SEMICONDUCTOR DEVICE, AND TRANSISTOR

(75) Inventors: Satoru TAKASAWA, Sammu-shi (JP); Masanori Shirai, Sammu-shi (JP); Satoru Ishibashi, Sammu-shi (JP); Tadashi Masuda, Tomisato-shi (JP); Yasuo Nakadai, Tomisato-shi (JP)

(73) Assignee: ULVAC, INC., Chigasaki-shi (JP)

(21) Appl. No.: 13/310,056

(22) Filed: Dec. 2, 2011

Related U.S. Application Data
(63) Continuation of application No. PCT/JP10/59631, filed on Jun. 7, 2010.

(30) Foreign Application Priority Data
Jun. 12, 2009 (JP) 2009-140933

(51) Int. Cl. H01L 29/78; H01L 23/48; B05D 5/12

(52) U.S. Cl. 257/288; 427/123; 257/741; 257/E29.255; 257/E23.01

(57) ABSTRACT

A technique is provided which prevents an increase in the resistivity of a conductive wiring film. A conductive layer containing Ca in a content rate of 0.3 atom % or more is provided on the surfaces of each of conductive wiring films which are to be exposed to a gas containing a Si atom in a chemical structure at a high temperature. When a gate insulating layer or a protection film containing Si is formed on the surface of the conductive layer, the Si atoms do not diffuse into the conductive layer and a resistance value does not increase, even if the conductive layer is exposed to the raw material gas containing Si in a chemical structure . Further, a CuCaO layer can be formed as an adhesive layer for preventing Si diffusion from a glass substrate or a silicon semiconductor.

This application is a continuation of International Application No. PCT/JP2010/059631 filed on Jun. 7, 2010, which claims priority to Japanese Patent Application No . 2009-140933, filed on Jun. 12, 2009. The entire disclosures of the prior applications are herein incorporated by reference in their entireties.

### BACKGROUND OF INVENTION

The present invention generally relates to an electronic device, a semiconductor device, and a transistor; and more particularly relates to achieving a lower resistance in a conductive wiring film of a liquid crystal display device.

### BACKGROUND ART

While an Al based wiring has been widely used for a TFT (Thin Film Transistor) panel conventionally, the TFT panel has been made increasingly larger in size with the popularity of large-size TVs; and it has recently been necessary for the TFT panel to have a lower wiring resistance and a lower panel cost. Accordingly, the need to replace the Al based wiring with a Cu based wiring having a lower resistance has increased.

When the Cu based wiring is used for the TFT panel, problems (such as, poor adhesiveness thereof to a glass substrate or abase film and occurrence of atom diffusion between a Si layer to be a base and the Cu based wiring (deterioration of barrier property)) occur.

A Mo based or Ti based barrier metal layer is generally used for the Al based wiring; and when an adhesive layer composed of a Mo film or a Ti film is formed for peeling prevention as an under layer which contacts a glass substrate or a Si semiconductor and a Cu layer is formed on the adhesive layer to configure a conductive wiring film having a two-layer structure, the adhesive layer works as both a bonding layer and a barrier layer and effectively prevents the peeling of the Cu layer from the glass substrate and Si diffusion from the Si semiconductor or the glass substrate into the Cu layer.

However, in the case of the Cu based wiring, even if the adhesive layer is disposed between the glass substrate and the Cu layer or between the silicon semiconductor and the Cu layer, the diffusion of Si from the glass substrate or the Si semiconductor can be prevented, but there arises a problem in that the resistivity of the conductive wiring film is increased during a process after the formation of the conductive wiring film (such as, the Cu layer) on the adhesive layer. See Japanese Patent Application Laid-Open Publication No. 2009-070881 and Japanese Patent Application Laid-Open Publication No. 2008-506040.

### SUMMARY OF THE INVENTION

The subject of the present invention is to provide a technique for preventing an increase in the resistivity of a conductive wiring film.

The inventors of the present invention have found that, when a Cu layer contacts a gas containing Si in a chemical structure at a high temperature, Si atoms diffuse into the Cu layer, resulting in an increase in the resistivity of the Cu layer.

Then, the inventors have arrived at the creation of the present invention by finding that it is effective to contain Ca in the Cu layer in order to prevent the Si diffusion.

Further, the inventors have also found a Ca content rate, which can effectively prevent the Si diffusion, in the Cu layer.

The present invention created by such finding is directed to a method for producing an electronic device comprising the steps of forming a conductive wiring film containing Cu and Ca at least on a surface thereof, and forming an insulating layer containing silicon on the surface of the conductive wiring film, wherein the conductive wiring film contains Cu atoms in more than 50 atom % and contains Ca atoms in not less than 0.3 atom % with respect to a total number of atoms of numbers of Cu atoms and Ca atoms.

Further, the present invention is directed to the method for producing an electronic device, in which Ca atoms are contained in a range of 5.0 atom % or less with respect to the total number of atoms of the numbers of Cu atoms and Ca atoms.

Further, the present invention is directed to the method for producing an electronic device, in which a step of forming the insulating layer includes a step of introducing silane based gas to form a silicon compound on the conductive wiring film by a CVD method.

Further, the present invention is directed to an electronic device comprising a conductive wiring film containing Cu and Ca at least on a surface thereof, and an insulating layer which contains silicon and is formed on the surface of the conductive wiring film, in which the conductive wiring film contains Cu in more than 50 atom % and contains Ca atoms in 0.3 atom % or more with respect to a total number of atoms of numbers of Cu atoms and Ca atoms.

Further, the present invention is directed to a semiconductor device comprising a conductive wiring film containing Cu and Ca at least on a surface thereof, and an insulating layer which contains silicon and is formed on the surface of the conductive wiring film, in which the conductive wiring film contains Cu in more than 50 atom % and contains Ca in 0.3 atom % or more with respect to a total number of atoms of numbers of Cu atoms and Ca atoms.

Further, the present invention is directed to a transistor comprising a conductive wiring film containing Cu and Ca at least on a surface thereof, and an insulating layer which contains silicon and is formed on the surface of the conductive wiring film, in which the conductive wiring film contains Cu in more than 50 atom % and contains Ca in 0.3 atom % or more with respect to a total number of atoms of numbers of Cu atoms and Ca atoms.

Further, the present invention is directed to the transistor, in which a gate electrode film is formed by the conductive wiring film, and a gate insulating film which contacts the gate electrode film is formed by the insulating layer.

Further, the present invention is directed to the transistor, in which the gate insulating film is formed in contact with raw material gas containing Si and the gate electrode film.

Further, the present invention is directed to the transistor comprising a source region, a drain region disposed apart from the source region, and a semiconductor region located between the source region and the drain region, in which the gate insulating film is disposed in contact with the semiconductor region, the gate electrode film is disposed in contact with the gate insulating film, and a region between the source region and the drain region is brought into a conduction state by a charge layer formed in the semiconductor region with a voltage applied to the gate electrode film.

Further, the present invention is directed to the transistor, in which a source electrode film and a drain electrode film are formed by the conductive wiring film, and an insulating film or an interlayer insulating film which contacts the source electrode film and the drain electrode film is formed by the insulating layer.

Further, the present invention is directed to the transistor, in which the insulating film is formed in a state where raw material gas containing Si is brought into contact with the source electrode film and the drain electrode film.

Further, the present invention is directed to the transistor comprising a source region, a drain region disposed apart from the source region, a semiconductor region located between the source region and the drain region, a gate insulating film disposed in contact with the semiconductor region, and a gate electrode film disposed in contact with the gate insulating film, in which a region between the source region and the drain region becomes conductive by a charge layer formed in the semiconductor region with a voltage applied to the gate electrode film.

### EFFECTS OF THE INVENTION

The resistance value of a conductive wiring film is not increased even when a thin film containing Si is formed on the conductive wiring film.

Since the resistance value of a conductive layer is small, it is possible to form the conductive wiring film by the conductive layer and it is also possible to configure the conductive wiring film with two layers of an adhesive layer and the conductive layer.

### BRIEF DESCRIPTION OF THE DRAWINGS

FIG. 1A is a diagram (1) for illustrating a step of manufacturing a liquid crystal display device of the present invention.

FIG. 1B is a diagram (1) for illustrating a step of manufacturing a liquid crystal display device of the present invention.

FIG. 1C is a diagram (1) for illustrating a step of manufacturing a liquid crystal display device of the present invention.

FIG. 2A is a diagram (2) for illustrating a step of manufacturing a liquid crystal display device of the present invention.

FIG. 2B is a diagram (2) for illustrating a step of manufacturing a liquid crystal display device of the present invention.

FIG. 2C is a diagram (2) for illustrating a step of manufacturing a liquid crystal display device of the present invention.

FIG. 3A is a diagram (3) for illustrating a step of manufacturing a liquid crystal display device of the present invention.

FIG. 3B is a diagram (3) for illustrating a step of manufacturing a liquid crystal display device of the present invention.

FIG. 3C is a diagram (3) for illustrating a step of manufacturing a liquid crystal display device of the present invention.

FIG. 4 is a diagram for illustrating a positional relationship between an adhesive layer and a conductive layer.

FIG. 5 is a diagram for illustrating an apparatus for manufacturing a conductive wiring film of the present invention.

FIG. 6 is a graph showing a relationship between an SiH₄ processing temperature and a resistivity of a conductive wiring film of the present invention.

FIG. 7 is a graph showing a relationship between an SiH₄ processing temperature and a resistivity of a conductive wiring film made of pure Cu.

FIG. 8 is a graph showing a relationship between a Ca content rate in a conductive wiring film of the present invention and respective resistivity values before and after SiH₄ processing for the conductive wiring film of the present invention.

FIG. 9 is a graph of a result of an auger analysis showing a depth-direction composition of a conductive wiring film including an adhesive layer composed of a CuCaO film and a pure Cu layer before SiH₄ processing.

FIG. 10 is a graph of a result of an auger analysis showing a depth-direction composition of a conductive wiring film including an adhesive layer composed of a CuCaO film and a pure Cu layer after SiH₄ processing.

FIG. 11 is a graph of a result of an auger analysis showing a depth-direction composition of a conductive wiring film in the present invention before SiH₄ processing.

FIG. 12 is a graph of a result of an auger analysis showing a depth-direction composition of a conductive wiring film in the present invention after SiH₄ processing.

### DETAILED DESCRIPTION OF THE INVENTION

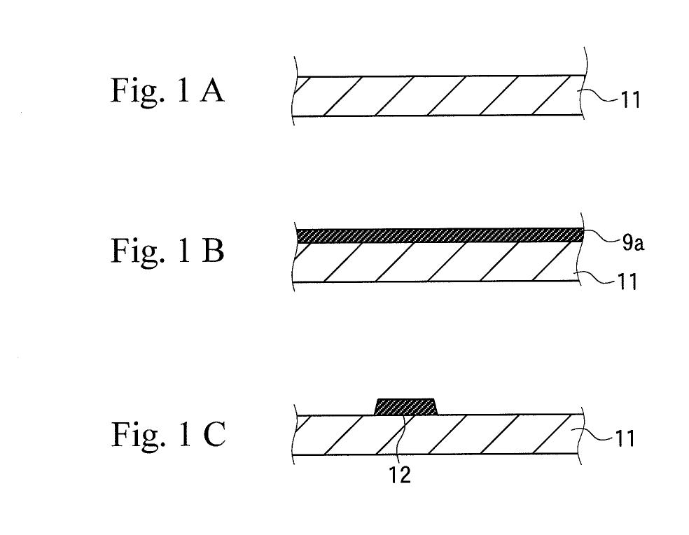

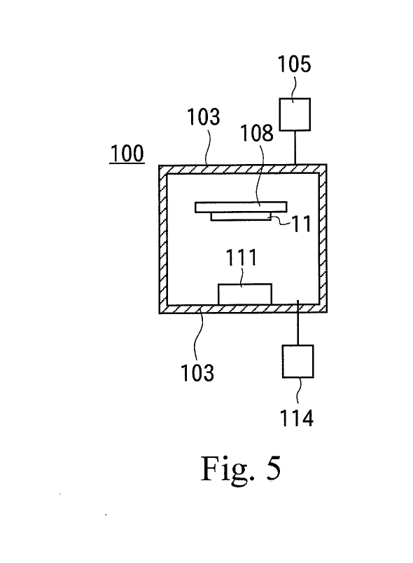

Reference numeral 11 of FIG. 1A indicates a substrate used for a transistor manufacturing method of the present invention; and reference numeral 100 of FIG. 5 indicates a film forming apparatus for forming a conductive layer on the surface of the substrate 11.

The film forming apparatus 100 includes a vacuum chamber 103; and a vacuum exhaust system 114 is connected to the vacuum chamber 103.

A copper alloy target 111 is disposed in the vacuum chamber 103; and a substrate holder 108 is disposed at a position facing the copper alloy target 111. The inside of the vacuum chamber 103 is evacuated, the substrate 11 is carried into the vacuum chamber 103 in a state such that a vacuum atmosphere is kept therein, and the substrate 11 is held by the substrate holder 108. This substrate 11 is a transparent substrate made of glass.

A gas introduction system 105 is connected to the vacuum chamber 103; and when sputtering gas (here, Ar gas) and oxygen-containing gas (here, O₂ gas) are introduced thereto from the gas introduction system 105 while the inside of the vacuum chamber 103 is evacuated and the copper alloy target 111 is sputtered at a predetermined pressure, sputtering particles made of material composing the copper alloy target 111 reach the surface of the substrate 11, thereby forming an adhesive layer on the surface of the substrate 11.

The copper alloy target 111 contains Ca (calcium) and copper; and the adhesive layer contains oxygen, Ca and Cu (here, expressed by CuCaO layer).

Next, the introduction of the oxygen-containing gas and the sputtering gas is stopped; and after the inside of the vacuum chamber 103 has once vacuum-exhausted so as to be a high-vacuum atmosphere, the sputtering gas is introduced thereinto from the gas introduction system 105 and the copper alloy target 111 is sputtered in a sputtering-gas atmosphere without including the oxygen-containing gas, whereby a conductive layer is formed on the adhesive layer.

When the sum of the weight of Cu and the weight of the Ca is 100, Ca is contained in the copper alloy target 111 in 0.3 atom % or more. That is, assuming that a Ca content rate (atom %) is evaluated by (number of Ca atoms)/(number of Ca atoms+number of Cu atoms)×100, the copper alloy target 111 has a Ca content rate of 0.3 atom % or more. Here, assuming that a Cu content rate (atom %) equals (number of Cu atoms)/(number of Ca atoms+number of Cu atoms)×100, the Cu content rate of this copper alloy target 111 exceeds 50 atom %.

In a case of a thin film, assuming that a Ca content rate (atom %) is evaluated by (number of Ca atoms)/(number of Ca atoms+number of Cu atoms)×100 and a Cu content rate (atom %) is evaluated by (number of Cu atoms)/(number of Ca atoms+number of Cu atoms)×100, a ratio of Cu and Ca in a thin film formed from the copper alloy target 111 is the same as that in the copper alloy target 111, so that the conductive layer on the adhesive layer has a Ca content rate (atom %)of 0.3 atom % or more and the Cu content rate (atom %) of a value exceeding 50 atom %.

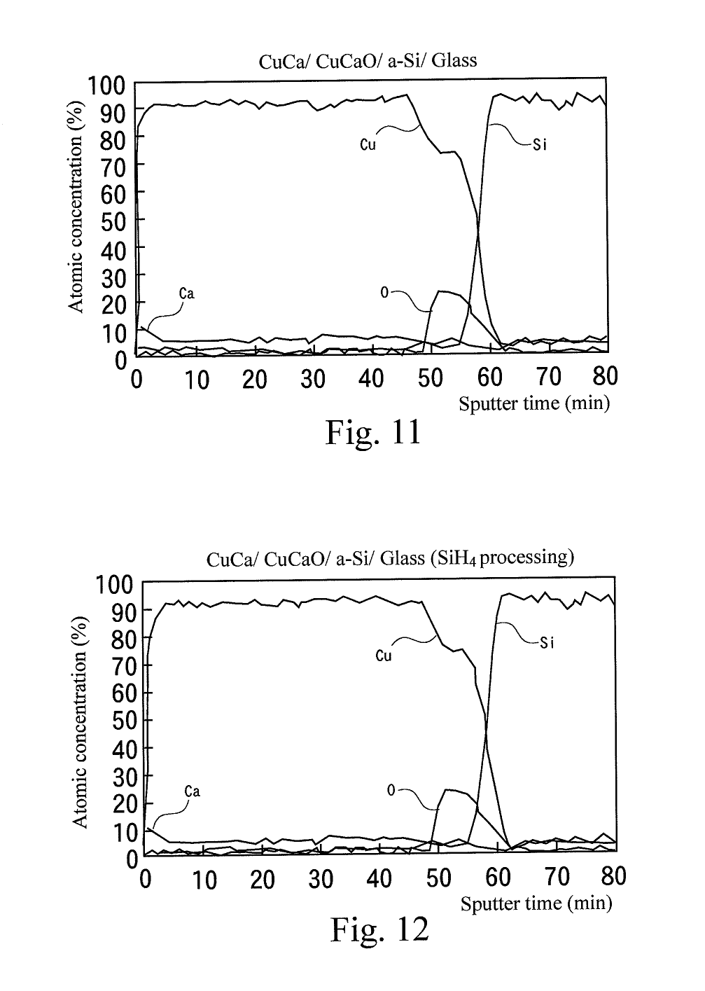

The conductive layer has a low Ca content rate and does not contain oxygen, and thus has an electrical conductivity at the same level as pure copper. When the conductive layer is formed on the adhesive layer, a conductive wiring film 9a composed of the two layers of the adhesive layer and the conductive layer is formed on the substrate 11 (FIG. 1B). Reference numerals 51 and 52 of FIG. 4 indicate the adhesive layer and the conductive layer, respectively. After the formation of the conductive wiring film 9a, the substrate 11 is taken out of the vacuum chamber 103, the conductive wiring film 9a is patterned in a photolithography step and an etching step, and a gate electrode film 12 composed of a part of the conductive wiring film 9a is formed on the substrate 11 (FIG. 10).

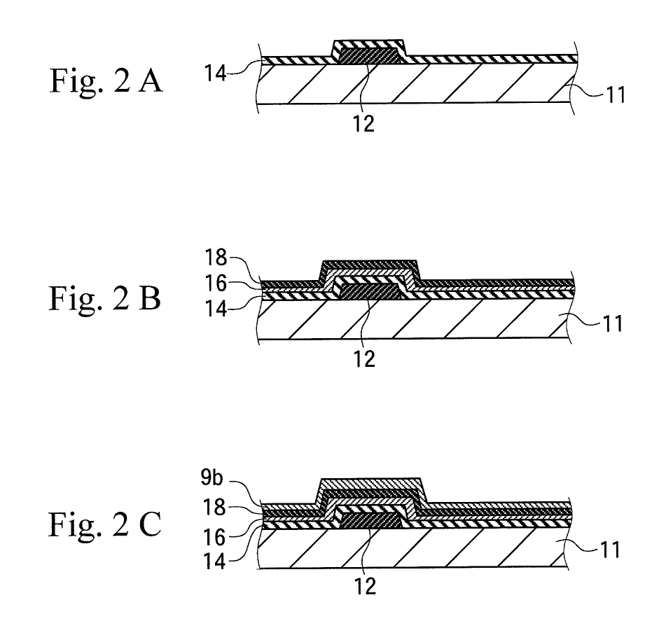

Next, the substrate 11 is carried into a CVD chamber, Si raw material gas containing Si in a chemical structure (such as SiH₄ gas), and reactive gas reacting with the Si raw material gas are introduced thereinto; and a gate insulating layer 14, which is made of a silicon compound and has insulation property, is formed so as to cover the exposed part of the substrate 11 and the gate electrode film 12 (FIG. 2A).

At this time, the gate electrode film 12 composed of a part of the conductive wiring film 9a is exposed to the Si raw material gas containing Si in a chemical structure, while being heated at a temperature higher than the temperature for the formation of a protection film which will be described later (temperature of 250° C. or more). The conductive layer 52, which contains Ca in 0.3 atom % or more, is exposed on the surface of the gate electrode film 12 (FIG. 4), whereby Ca prevents Si diffusion and the resistance value does not increase. The gate insulating layer 14 is an insulating layer made of SiN, but the gate insulating layer 14 may be an insulating layer made of SiO₂ or an insulating layer made of SiON.

Next, a first silicon layer 16 and a second silicon layer 18 are formed, in this order from the side of the substrate 11, on the gate insulating layer 14 by a CVD method (FIG. 2B).

The second silicon layer 18 has a resistance value lower than the first silicon layer 16 by impurity doping. Each of the first and second silicon layers 16 and 18 is composed of an amorphous silicon layer, but the first and second silicon layers 16 and 18 may be made of a single crystal or a poly crystal.

The substrate 11 having the second silicon layer 18 exposed on the surface thereof is transferred to the above-described film forming apparatus 100 or a film forming apparatus different from the apparatus 100; a copper alloy target 111, which contains Ca at a content rate (atom %) of 0.3 atom % or more and Cu at a content rate (atom %) exceeding 50 atom % as with the composition of the copper alloy target 111 in the above-described film forming apparatus 100, is sputtered; and a conductive wiring film 9b is formed on the second silicon layer 18 (FIG. 2C).

This conductive wiring film 9b is also composed of an adhesive layer 51 containing O and a conductive layer 52 without containing O, as shown in FIG. 4, as with the conductive wiring film 9a, a part of which forms the gate electrode film 12, and each of the adhesive layer 51 and the conductive layer 52 has a Cu content rate exceeding 50 atom % and a Ca content rate of 0.3 atom % or more.

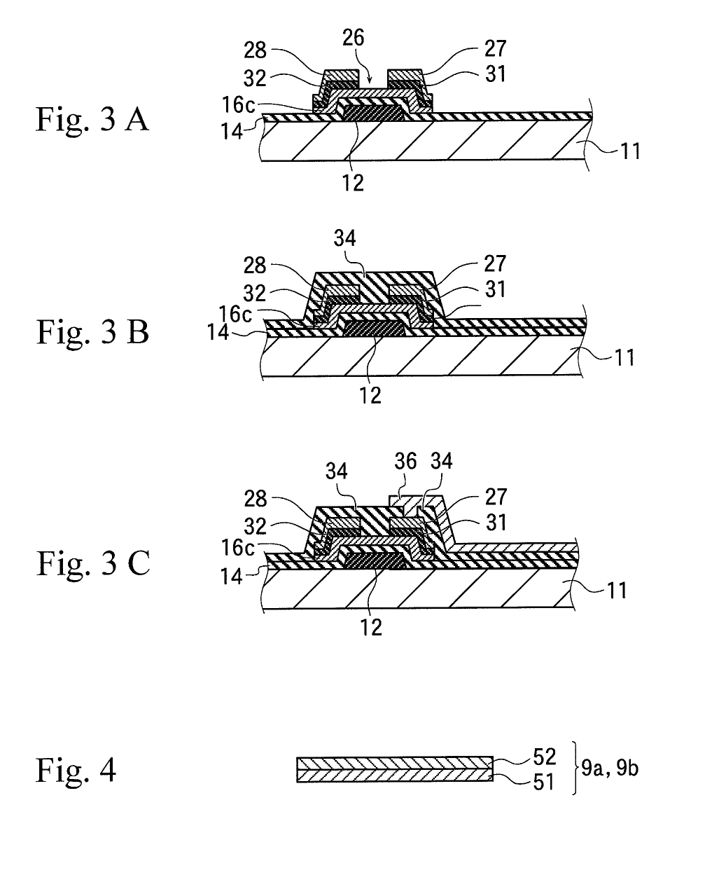

A source electrode film 27 and a drain electrode film 28, which are separated from each other, as shown in FIG. 3A, are formed from the conductive wiring film 9b shown in FIG. 2C by a photolithography step and an etching step; and a source region 31 is formed by a part of the second silicon layer 18 located under the bottom surface of the source electrode film 27 and a drain region 32 is formed by a part thereof located under the bottom surface of the drain electrode film 28. At this time, an opening 26 is formed between the source region 31 and the drain region 32 and between the source electrode film 27 and the drain electrode film 28, and a semiconductor part 16c is formed from the first silicon layer 16 across a position under the source region 31, a bottom position of the opening 26, and a position under the drain region 32.

Next, the substrate 11 is carried into a CVD apparatus in a state of exposing the surface of the source electrode film 27, the surface of the drain electrode film 28, and the surface of the semiconductor part 16c at the bottom part of the opening 26; the substrate 11 is heated under vacuum exhaustion; Si raw material gas containing Si in a chemical structure (such as, SiH₄ gas), and reactive gas reacting with the Si raw material gas are introduced into the CVD apparatus; and a protection film 34, which is made of a silicon compound and has an insulating property (such as, a silicon nitride film (SiNₓ)) is formed so as to cover the source electrode film 27 and the drain electrode film 28 and fill the opening 26 (FIG. 3B).

When the protection film 34 is formed, the source electrode film 27 and the drain electrode film 28, each of which is composed of a part of the conductive wiring film 9b, are exposed to the Si raw material gas containing Si in a chemical structure while being heated at a temperature lower than the temperature in the formation of the gate insulating layer 14 (e.g., a temperature of 200° C. or more and lower than 300° C. at the highest).

The conductive layers 52 having a Ca content rate of 0.3 atom % or more are located on the respective surfaces of the source electrode film 27 and the drain electrode film 28 . Thus, Ca prevents Si diffusion and the resistance values thereof do not increase.

Next, a contact hole is formed in the protection film 34, and a transparent electrode film 36 to be connected to the source electrode film 27 or the drain electrode film 28 via the contact hole is formed (FIG. 3C).

In the transistor of the present invention, the conductivity types of the source region 31, the drain region 32, and the semiconductor part 16c are the same. In this case, the semiconductor part 16c has a low dopant concentration and has a higher resistance than the source region 31 and the drain region 32; and thus, the source region 31 and the drain region 32 are normally separated by the high resistance . When a voltage is applied to the gate electrode film 12 and an electric charge layer (accumulation layer) having a low resistance and the same conductivity type as that of the semiconductor part 16c is formed in the semiconductor part 16c, the resistance value between the source region 31 and the drain region 32 is decreased by the electric charge layer; and thus, the source region 31 and the drain region 32 are connected to each other.

Meanwhile, the present invention includes a case in which the source region 31 and the drain region 32 have the same conductivity type, but the semiconductor part 16c has the conductivity type opposite to that of the source region 31 and the drain region 32. In this case, the source region 31 and the drain region 32 are separated from each other by a p-n junction; and when a voltage is applied to the gate electrode film 12 and an electric charge layer (inversion layer) having the conductivity type inverse to that of the semiconductor part 16c is formed in the semiconductor part 16c, the source region 31 and the drain region 32 can be connected to each other by the electric charge layer.

In any case, voltage application and stop of the voltage application are performed by the conduction and cutoff of the transistor with respect to the transparent electrode film 36. A common electrode is disposed over the transparent electrode film 36 and spaced apart from the transparent electrode film 36; and liquid crystal is disposed between the transparent electrode film 36; and the common electrode. When voltage application and stop of voltage application are switched for the transparent electrode film 36, polarization of the liquid crystal is controlled and an amount of light passing through the liquid crystal and the common electrode is changed; and thus, a desired display is performed.

Further, while each of the conductive wiring films 9a and 9b has a two-layer structure of the adhesive layer 51 and the conductive layer 52 and the conductive layer 52 is used as a low-resistance layer, a low-resistance layer (such as, a pure copper layer) may be provided between the conductive layer 52 and the adhesive layer 51 to form a conductive wiring film having a three-layer structure. Further, a layer or the like containing an element other than Ca or oxygen may be provided therebetween to forma conductive wiring film having a laminated structure of four or more layers.

The adhesive layer 51 and the conductive layer 52 can be formed using the same target and Ca may be contained in the adhesive layer 51, but the adhesive layer may be a Cu layer containing oxygen without containing Ca. Further, the adhesive layer may be a Ti layer or a Mo layer.

In the above-described embodiment, the SiH₄ gas is illustrated as a gas containing Si in a chemical structure, but the present invention is not limited thereto and widely includes other kinds of gas containing Si (such as, e.g., Si₂H₆).

### EXAMPLE

After a wiring film was formed on a glass substrate, the temperature of the glass substrate was increased in a vacuum atmosphere, and SiH₄ gas processing of exposing the wiring film to the SiH₄ gas was performed while the wiring film was being heated; and then, resistivity was measured.

In the SiH₄ gas processing, after the temperature of the glass substrate was increased by heating the glass substrate in the vacuum atmosphere so as to reach a temperature in a range of 250 to 300° C., the SiH₄ gas and N₂ gas were introduced into the vacuum atmosphere in a manner such that the SiH₄ gas had a pressure of 8.5 Pa and the N₂ gas had a pressure of 101.5 Pa (total pressure is 110 Pa of the total value); and the wiring film was exposed to the gas atmosphere for an exposure time of 60 seconds.

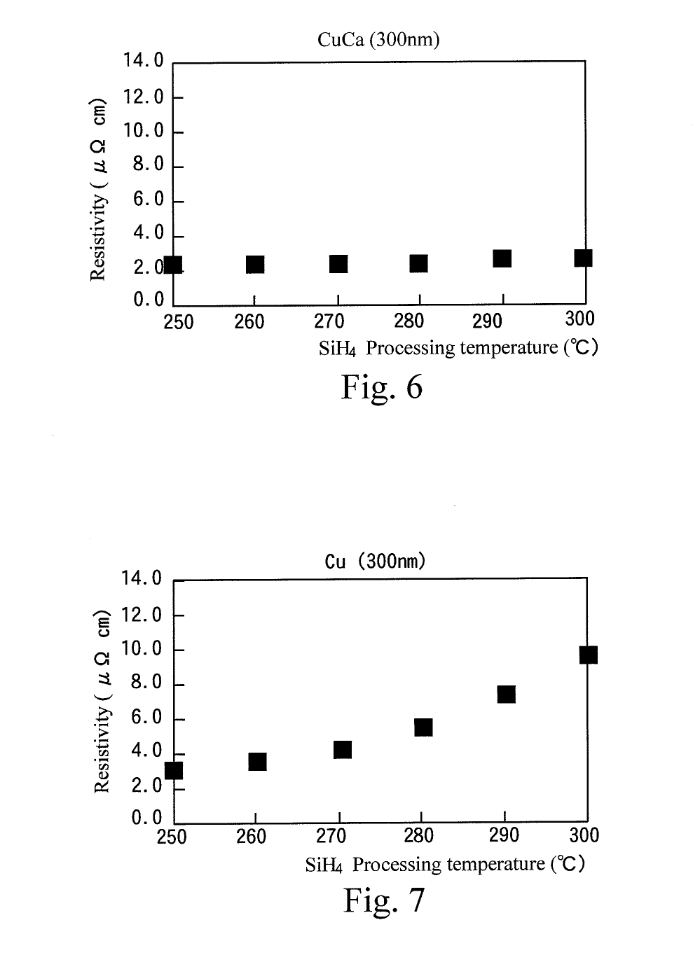

FIG. 6 shows a result of forming, on a glass substrate, a conductive wiring film (CuCa layer of 300 nm) having the same structure and composition as the conductive wiring film composing the gate electrode film, source electrode film, and drain electrode film in the above-described example, performing the SiH₄ gas processing while the temperature was changed, and measuring the resistivity. The increase of the resistivity is not observed.

FIG. 7 also shows a relationship between the temperature and the resistivity change of a wiring film formed on a glass substrate; and FIG. 7 shows a case of a wiring film (thickness of 300 nm) made of pure copper. In FIG. 7, the resistivity increases with the increase of the temperature.

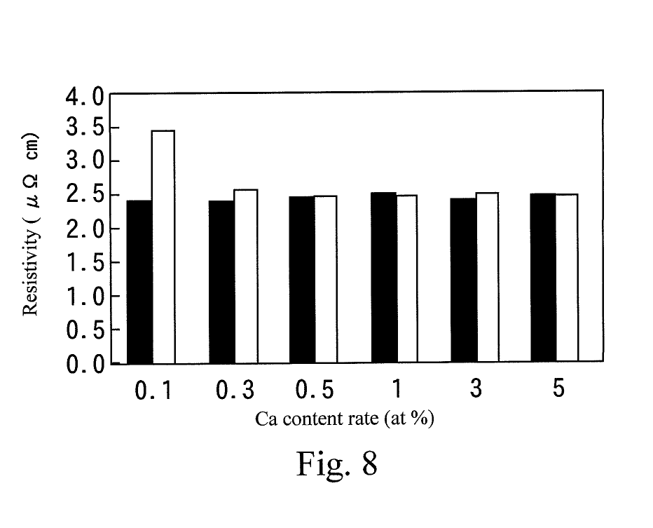

FIG. 8 is a graph showing a relationship between a Ca content rate in a conductive layer and respective resistivity before and after the SiH₄ processing, in the conductive wiring film having an adhesive layer and the conductive layer. Here the SiH₄ gas processing was performed as follows: after a glass substrate was heated in the vacuum atmosphere so as to reach 270° C., the SiH₄ gas and the N₂ gas were introduced into the vacuum atmosphere in a manner such that the SiH₄ gas had a pressure of 8.5 Pa and the N₂ gas had a pressure of 101.5 Pa (total pressure: 110 Pa), and a wiring film was exposed to the gas atmosphere for an exposure time of 60 seconds.

Of the two bars shown on each number of Ca content rate in the graph, the left one shows a resistivity before the SiH₄ processing and the right one shows a resistivity after the SiH₄ processing.

The increase of the resistivity is observed at a Ca content rate of 0.1 atom %, but the resistivity does not increase at a Ca content rate of 0.3 atom % or more. Accordingly, the Ca content rate in the conductive layer is preferably 0.3 atom % or more.

Since the ratio of Cu and Ca in a thin film formed from a Cu target containing Ca is preferably 0.3 atom % or more and the ratios thereof in the target and the thin film are same, the Ca content rate in the target is also preferably 0.3 atom % or more.

Further, since the resistivity does not increase if the Ca content rate is at least 5 atom % or less, the Ca content rate is preferably 5 atom % or less. When the Ca content rate is higher than 5 atom % , the same effect is obtained, but sometimes the production of the target becomes difficult.

Next, an amorphous silicon layer was formed on a glass substrate, a wiring layer was formed on the surface thereof, and respective depth-direction compositions of the wiring film before and after the SiH₄ processing were measured by Auger analysis while the surface thereof is being removed by sputtering. The condition of the SiH₄ processing is the same as that of the bar graph (SiH₄ gas processing was performed as follows: after the glass substrate was heated in the vacuum atmosphere so as to reach 270° C., the SiH₄ gas and the N₂ gas were introduced into the vacuum atmosphere in a manner such that the SiH₄ gas had a pressure of 8.5 Pa and the N₂ gas had a pressure of 101.5 Pa (total pressure: 110 Pa), and the wiring film was exposed to the gas atmosphere for an exposure time of 60 seconds).

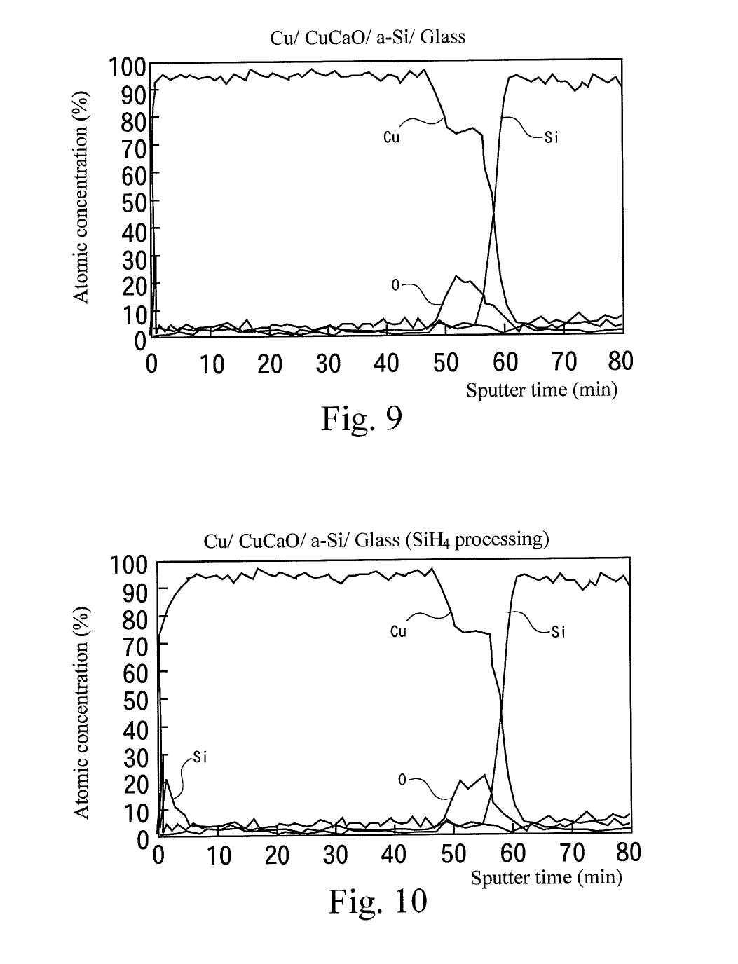

FIG. 9 shows an analysis result of a wiring film before the SiH₄ processing, the wiring film having an adhesive layer of a Cu film containing Ca and O which was formed on the amorphous silicon layer and a pure copper layer which was laminated thereon; and FIG. 10 is an analysis result of the wiring film after the SiH₄ processing. It is found that Si intrudes in the vicinity of the wiring film surface (vicinity of the surface of the pure copper layer) after the SiH₄ processing.

FIG. 11 is an analysis result of a wiring film before the SiH₄ processing, the wiring film having an adhesive layer of a Cu film containing Ca and O which was formed on the amorphous silicon layer and a conductive layer with a Ca content rate of 0.3 atom % which was formed thereon; and FIG. 12 is an analysis result of the wiring film after the SiH₄processing. Si intrusion is not found and this shows the reason why the resistivity was not increased.

Ca aggregates on the surface of the conductive layer in high concentration and this is presumed to be the reason why the diffusion prevention capability is high even at a low content rate of 0.3 atom %.

What is claimed is:

1. A method for producing an electronic device, comprising the steps of:
forming a conductive wiring film containing Cu and Ca at least on a surface thereof; and
forming an insulating layer containing silicon on the surface of the conductive wiring film,
wherein the conductive wiring film contains Cu atoms in more than 50 atom % and contains Ca atoms in at least 0.3 atom % with respect to a total number of atoms of numbers of Cu atoms and Ca atoms.

2. The method for producing an electronic device according to claim 1, wherein Ca atoms are contained in a range of at most 5.0 atom % with respect to the total number of atoms of the numbers of Cu atoms and Ca atoms.

3. The method for producing an electronic device according to claim 1, wherein a step of forming the insulating layer includes a step of introducing silane based gas to forma silicon compound on the conductive wiring film by a CVD method.

4. An electronic device, comprising:
a conductive wiring film containing Cu and Ca at least on a surface thereof; and
an insulating layer which contains silicon and is formed on the surface of the conductive wiring film,
wherein the conductive wiring film contains Cu in more than 50 atom % and contains Ca atoms in at least 0.3 atom % with respect to a total number of atoms of numbers of Cu atoms and Ca atoms.

5. A semiconductor device, comprising:
a conductive wiring film containing Cu and Ca at least on a surface thereof; and
an insulating layer which contains silicon and is formed on the surface of the conductive wiring film,
wherein the conductive wiring film contains Cu in more than 50 atom % and contains Ca in at least 0.3 atom % with respect to a total number of atoms of numbers of Cu atoms and Ca atoms.

6. A transistor, comprising:
a conductive wiring film containing Cu and Ca at least on a surface thereof; and
an insulating layer which contains silicon and is formed on the surface of the conductive wiring film,
wherein the conductive wiring film contains Cu in more than 50 atom % and contains Ca in at least 0.3 atom % with respect to a total number of atoms of numbers of Cu atoms and Ca atoms.

7. The transistor according to claim 6, wherein a gate electrode film is formed by the conductive wiring film, and a gate insulating film which contacts the gate electrode film is formed by the insulating layer.

8. The transistor according to claim 7, wherein the gate insulating film is formed in contact with raw material gas containing Si and the gate electrode film.

9. The transistor according to claim 7, comprising:
a source region;
a drain region disposed apart from the source region; and
a semiconductor region located between the source region and the drain region,
wherein the gate insulating film is disposed in contact with the semiconductor region, the gate electrode film is disposed in contact with the gate insulating film, and a region between the source region and the drain region is brought into a conduction state by a charge layer formed in the semiconductor region with a voltage applied to the gate electrode film.

10. The transistor according to claim 9, wherein a source electrode film and a drain electrode film are formed by the conductive wiring film, and an insulating film or an interlayer insulating film which contacts the source electrode film and the drain electrode film is formed by the insulating layer.

11. The transistor according to claim 10, wherein the insulating film is formed in a state where raw material gas containing Si is brought into contact with the source electrode film and the drain electrode film.

12. The transistor according to claim 7, further comprising a source region, a drain region disposed apart from the source region, a semiconductor region located between the source region and the drain region, a gate insulating film disposed in contact with the semiconductor region, and a gate electrode film disposed in contact with the gate insulating film, wherein a region between the source region and the drain region becomes conductive by a charge layer formed in the semiconductor region with a voltage applied to the gate electrode film.
